(19) United States
(12) Patent Application Publication
(10) Pub. No.: US 2026/0353922 A1
(43) Pub. Date: Nov. 5, 2026

(54) DISPLAY DEVICE AND ELECTRONIC DEVICE INCLUDING THE SAME

(71) Applicant: Samsung Display Co., Ltd., Yongin-si (KR)

(72) Inventors: Dong Hee SHIN, Yongin-si (KR); Kyung Ho Kim, Yongin-si (KR); Jung Hwan Hwang, Yongin-si (KR)

(73) Assignee: Samsung Display Co., Ltd., Yongin-si (KR)

(21) Appl. No.: 19/448,744

(22) Filed: Jan. 14, 2026

(30) Foreign Application Priority Data
Mar. 4, 2025 (KR) 10-2025-0027384
Jul. 11, 2025 (KR) 10-2025-0093506

(51) Int. Cl. H10K 59/121; H10K 39/34; H10K 59/124

(52) U.S. Cl. CPC H10K 59/1213; H10K 39/34; H10K 59/124

(57) ABSTRACT

A display device includes a substrate, an element layer on the substrate and including a light-emitting element and a light-receiving element, and a circuit layer between the substrate and the element layer, where the circuit layer includes a first stack including a light-emission transistor connected to the light-emitting element, a first line stack on the first stack and including a first line connected to the light-emission transistor, a second stack on the first line stack and including a light-receiving transistor connected to the light-receiving element, and a second line stack on the second stack and including a second line connected to at least one of the light-emission transistor and the light-receiving transistor.

### CROSS-REFERENCE TO RELATED APPLICATIONS

This application is based on and claims priority to Korean Patent Application No. 10-2025-0027384, filed on Mar. 4, 2025, in the Korean Intellectual Property Office, and Korean Patent Application No. 10-2025-0093506, filed on Jul. 11, 2025, in the Korean Intellectual Property Office, the disclosures of which are incorporated by reference herein in their entireties.

### BACKGROUND

### 1. Field

The present disclosure relates to a display device and an electronic device including the same.

### 2. Description of Related Art

As the information society develops, a demand for a display device for displaying an image is increasing in various forms. For example, the display device is applied to various electronic devices such as smartphones, digital cameras, notebook computers, navigation systems, and smart televisions.

The display device may be embodied as a flat panel display device such as a liquid crystal display device, a field emission display device, an organic light-emitting display device, or the like. Among the flat panel display devices, the light-emitting display device includes a light-emitting element in which each of a pixels of a display panel can emit light by itself, thereby displaying an image without a backlight unit that provides light to the display panel.

The display device may include a photo sensor that is embedded in a display panel that displays an image and senses light. The photo sensor may include a light-receiving element capable of collecting light.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Provided is a display device having high resolution including a light-emitting element and a light-receiving element, and an electronic device including the same.

Additional aspects will be set forth in part in the description which follows and, in part, will be apparent from the description, or may be learned by practice of the presented embodiments.

According to an aspect of an example embodiment, a display device may include a substrate, an element layer on the substrate and including a light-emitting element and a light-receiving element, and a circuit layer between the substrate and the element layer, where the circuit layer may include a first stack including a light-emission transistor connected to the light-emitting element, a first line stack on the first stack and including a first line connected to the light-emission transistor, a second stack on the first line stack and including a light-receiving transistor connected to the light-receiving element, and a second line stack on the second stack and including a second line connected to at least one of the light-emission transistor and the light-receiving transistor.

The light-receiving transistor may not overlap the light-emission transistor in a first direction perpendicular to an upper surface of the substrate.

The light-receiving transistor may be overlapped by the light-emission transistor in a first direction perpendicular to an upper surface of the substrate.

The display device may include a common application line connected to both the light-emission transistor and the light-receiving transistor.

The common application line may include a first end adjacent to the light-emission transistor, a second end adjacent to the light-receiving transistor, and a connection portion connecting the first end to the second end.

The first stack may include a first insulating film, the second stack may include a second insulating film, the circuit layer may include a first contact hole extending through the second insulating film and the first insulating film and a second contact hole extending through the second insulating film, the first contact hole connects the first end of the common application line to the light-emission transistor, the second contact hole connects the second end of the common application line to the light-receiving transistor, and the connection portion of the common application line is between the first contact hole and the second contact hole.

The common application line may include at least one of a reference voltage line, an initialization voltage line, a scan write line, and a low voltage power line.

The light-receiving transistor may not be in the first stack and the light-emission transistor may not be in the second stack.

According to an aspect of an example embodiment, a display device may include a substrate, an element layer on the substrate and comprising a light-emitting element and a light-receiving element, and a circuit layer between the substrate and the element layer, where the circuit layer may include a first active layer on the substrate, a first gate layer on the first active layer, a first source/drain layer on the first gate layer, a second active layer on the first source/drain layer, a second gate layer on the second active layer, a second source/drain layer on the second gate layer, a light-emission transistor connected to the light-emitting element, the light-emission transistor comprising a first semiconductor area, a first electrode, and a second electrode in the first active layer, and a first gate electrode in the first gate layer, a light-receiving transistor connected to the light-receiving element, the light-receiving transistor comprising a second semiconductor area, a third electrode, and a fourth electrode in the second active layer, and a second gate electrode in the second gate layer, a first line on the first source/drain layer and connected to the light-emission transistor, and a second line on the second source/drain layer and connected to at least one of the light-emission transistor and the light-receiving transistor.

The light-receiving transistor may not overlap the light-emission transistor in a first direction perpendicular to an upper surface of the substrate.

The light-receiving transistor may be overlapped by the light-emission transistor in a first direction perpendicular to an upper surface of the substrate.

The display device may include a common application line connected to both the light-emission transistor and the light-receiving transistor.

The common application line may include a first end adjacent to the light-emission transistor, a second end adjacent to the light-receiving transistor, and a connection portion connecting the first end to the second end.

The common application line may be in the second source/drain layer.

The circuit layer may include a first connection electrode on the first source/drain layer, a first contact hole extending through at least one insulating film between the first source/drain layer and the second source/drain layer, a second contact hole extending through at least one insulating film between the second active layer and the second source/drain layer, the first contact hole connects the first end of the common application line to the light-emission transistor, the second contact hole connects the second end of the common application line to the light-receiving transistor, and the connection portion of the common application line is between the first contact hole and the second contact hole.

The common application line may include at least one of a reference voltage line, an initialization voltage line, a scan write line, and a low voltage power line.

The circuit layer may include a first stack including the light-emission transistor and a second stack including the light-receiving transistor, the light-receiving transistor may not be in the first stack and the light-emission transistor may not be in the second stack.

The circuit layer may include a first lower conductive layer between the substrate and the first active layer and a second lower conductive layer between the first source/drain layer and the second active layer.

The light-emission transistor may include a first lower gate electrode in the first lower conductive layer and the light-receiving transistor may include a second lower gate electrode in the second lower conductive layer.

According to an aspect of an example embodiment, an electronic device may include a display device configured to display an image, a processor configured to provide an image driving signal to the display device, and a power module configured to supply power to the display device and the processor, where the display device may include a substrate, an element layer on the substrate and including a light-emitting element and a light-receiving element, and a circuit layer between the substrate and the element layer, where the circuit layer may include a first stack including a light-emission transistor connected to the light-emitting element, a first line stack on the first stack and including a first line connected to the light-emission transistor, a second stack on the first line stack and including a light-receiving transistor connected to the light-receiving element, and a second line stack on the second stack and including a second line connected to at least one of the light-emission transistor and the light-receiving transistor.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view illustrating a display device according to an embodiment;

FIG. 2 is a plan view illustrating the display device of FIG. 1 according to an embodiment;

FIG. 3 is a cross-sectional view taken along a line X1-X1′ of FIG. 2 according to an embodiment;

FIG. 4 is a plan view illustrating a light-emitting pixel, a sensing pixel, various drivers, and various lines of a display device according to an embodiment;

FIG. 5 is a block diagram illustrating a light-emitting pixel, a sensing pixel, various drivers, and various lines of a display device according to an embodiment;

FIG. 6 is a plan view illustrating a display area of a display device according to an embodiment;

FIG. 7 is an equivalent circuit diagram illustrating a light-emitting pixel according to an embodiment;

FIG. 8 is an equivalent circuit diagram illustrating a sensing pixel according to an embodiment;

FIG. 9 is a cross-sectional view illustrating a light-emitting pixel according to an embodiment;

FIG. 10 is a cross-sectional view illustrating a sensing pixel according to an embodiment;

FIG. 11 is a table illustrating a layer-by-layer arrangement of lines connected to each of a light-emitting pixel and a sensing pixel, and a layer-by-layer arrangement of transistors respectively included in the light-emitting pixel and the sensing pixel of a display device, according to an embodiment.

FIG. 12 is a schematic layout diagram illustrating a display area of a display device according to each of a comparative example and some embodiments; and

FIG. 13 is an equivalent circuit diagram illustrating connection portions connecting a light-emitting pixel, a sensing pixel, and a common application line to each other according to an embodiment;

FIG. 14 is a layout diagram illustrating a portion of a display area according to an embodiment;

FIG. 15 is a layout diagram illustrating a first stack and a first line stack according to an embodiment;

FIG. 16 is a layout diagram illustrating a second stack and a second line stack according to an embodiment;

FIG. 17 is a cross-sectional view taken along a line X2-X2′ of FIGS. 14 to 16 according to an embodiment;

FIG. 18 is a cross-sectional view taken along a line X3-X3′ of FIGS. 14 to 16 according to an embodiment;

FIG. 19 is a block diagram of an electronic device according to an embodiment; and

FIG. 20 is a schematic diagram of an electronic device according to various embodiments.

### DETAILED DESCRIPTIONS

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

In addition, terms such as “unit” and “module” described in the specification may indicate a unit that processes at least one function or operation, and this may be implemented as hardware or software, or may be implemented as a combination of hardware and software.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

Hereinafter, embodiments of the present disclosure will be described in detail with reference to the accompanying drawings.

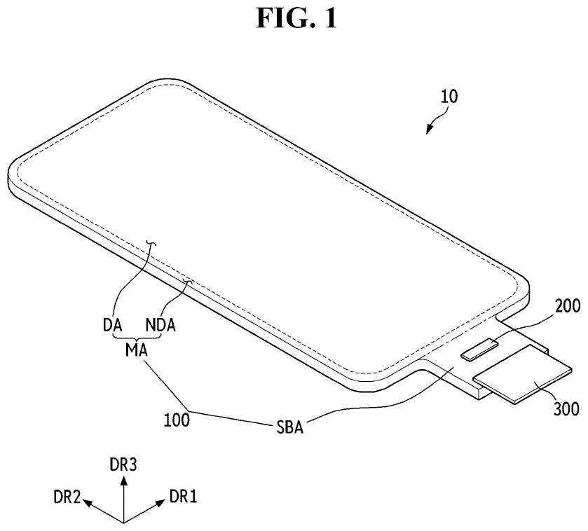

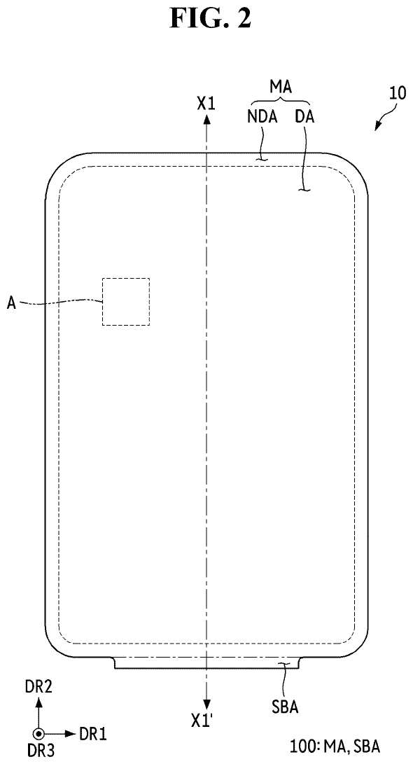

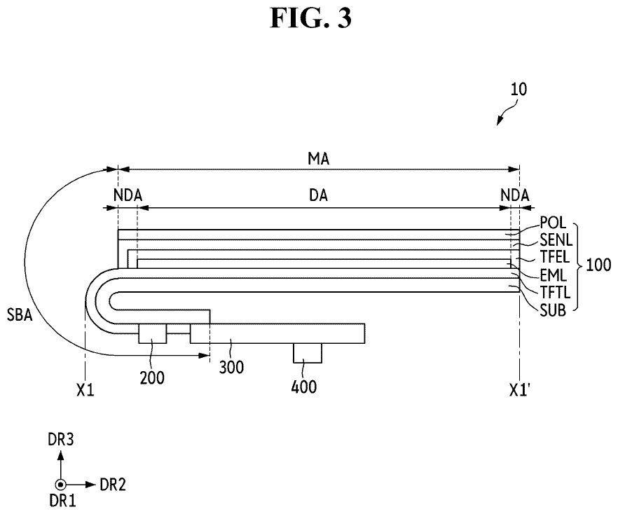

FIG. 1 is a perspective view illustrating a display device according to an embodiment. FIG. 2 is a plan view illustrating the display device of FIG. 1 according to an embodiment. FIG. 3 is a cross-sectional view taken along a line X1-X1′ of FIG. 2 according to an embodiment.

FIG. 1 illustrates a state in which a sub-area SBA of a display device 10 is flat, and FIGS. 2 and 3 illustrate a state in which the sub-area SBA of the display device 10 is bent.

Referring to FIGS. 1 to 3, the display device 10 is a device for displaying a moving image or a still image, and may be used as a display screen of various products such as a television, a laptop computer, a monitor, a billboard, an internet of things (IOT), and the like, as well as a mobile electronic device such as a mobile phone, a smart phone, a tablet personal computer (PC), a smart watch, a mobile communication terminal, an electronic notebook, an electronic book, a portable multimedia player (PMP), a navigation system, an ultra mobile PC (UMPC), and the like.

The display device 10 may include a display panel 100. The display panel 100 may be a light-emitting display panel such as an organic light-emitting display panel using an organic light-emitting diode, a quantum dot light-emitting display panel including a quantum dot light-emitting layer, an inorganic light-emitting display panel including an inorganic semiconductor, and a micro light-emitting display panel using a micro or nano light-emitting diode (LED) (micro LED or nano LED). Hereinafter, an example in which the display panel 100 is embodied as the organic light-emitting display panel will be mainly described. However, embodiments of the present disclosure are not limited thereto.

The display panel 100 may be formed to be flat. However, embodiments of the present disclosure are not limited thereto. For example, the display panel 100 may include a curved portion formed at each of left and right ends thereof and having a constant curvature or a varying curvature. In addition, the display panel 100 may be flexibly formed to be bent, curved, folded, or rolled.

The display panel 100 may include a main area MA corresponding to a display surface of the display device 10, and the sub-area SBA protruding from one side of the main area MA.

The main area MA may include a display area DA disposed in a significant portion of an inner area and a non-display area NDA disposed around the display area DA. The display area DA may be formed as a rectangular plane having a short side extending in a first direction DR1 and a long side extending in a second direction DR2. A corner at which the short side extending in the first direction DR1 and the long side extending in the second direction DR2 meet with each other may be rounded to have a predetermined curvature or may be formed at a right angle. However, a shape in a plan view of the display area DA is not limited to a quadrangle, and may have another polygonal shape, a circular shape, or an oval shape. The non-display area NDA may be disposed at an edge of the main area MA so as to surround the display area DA.

In the illustrated drawing, the first direction DR1 and the second direction DR2 intersect each other and may be first and second horizontal directions. For example, the first direction DR1 and the second direction DR2 may be orthogonal to each other. In addition, the third direction DR3 may be a vertical direction intersecting (for example, orthogonal to) the first direction DR1 and the second direction DR2. Unless otherwise defined, herein, a direction indicated by an arrow in each of the first to third directions DR1, DR2, and DR3 may be referred to as one side, and the opposite direction thereto may be referred to as the other side. In addition, “on top of”, “upper side”, “top”, “upper portion” and “upper surface” as used herein mean a direction as indicated by the arrow of the third direction DR3 based on the drawing, while “under”, “lower side”, “bottom,” “lower portion” and “lower surface” mean a direction opposite to the direction as indicated by the arrow of the third direction DR3 based on the drawing.

The sub-area SBA may be an area extending from a portion of one side extending in the first direction DR1 of the main area MA in the second direction DR2. The sub-area SBA may include a bendable area that is deformed into a bent shape.

As shown in FIG. 3, the sub-area SBA may include a bendable area deformable into a bent shape, a first sub-area disposed between one side of the main area MA and one side of the bendable area, and a second sub-area extending from the other side of the bendable area. When the bendable area is deformed into a bent shape, the second sub-area may be disposed on a rear surface of the display device 10 and overlap the main area MA. A display driving circuit 200 embodied as an integrated circuit (IC) may be mounted on the second sub-area SA2. A circuit board 300 may be bonded to one side of the second sub-area SA2. A touch driving circuit 400 embodied as an IC may be mounted on the circuit board 300.

As illustrated in FIG. 3, the display panel 100 of the display device 10 according to embodiments may include a substrate SUB, a circuit layer TFTL, an element layer EML, a encapsulation layer TFEL, a touch sensor layer SENL, and a polarization layer POL.

The substrate SUB may be made of an insulating material such as a polymer resin. For example, the substrate SUB may be made of polyimide. The substrate SUB may be a flexible substrate capable of bending, folding, rolling, or the like. Alternatively, the substrate SUB may be made of an insulating material such as glass.

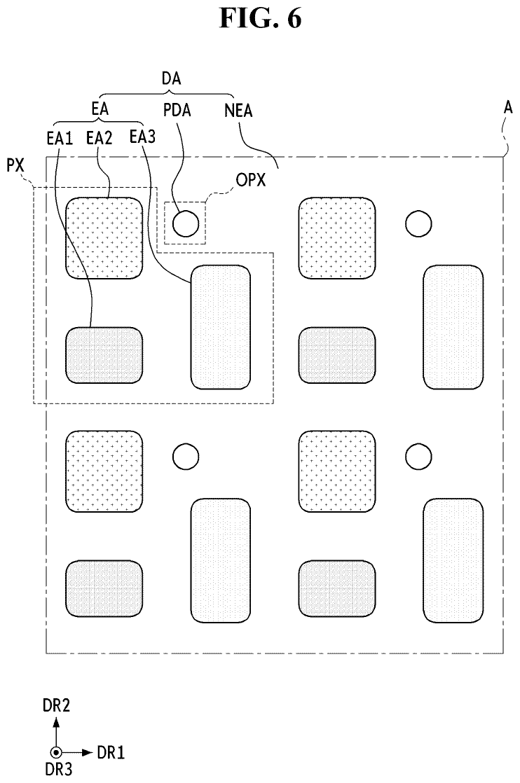

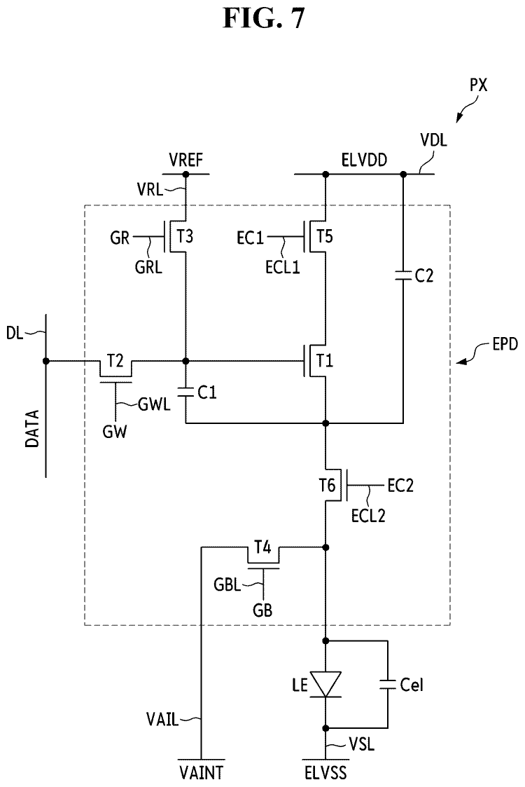

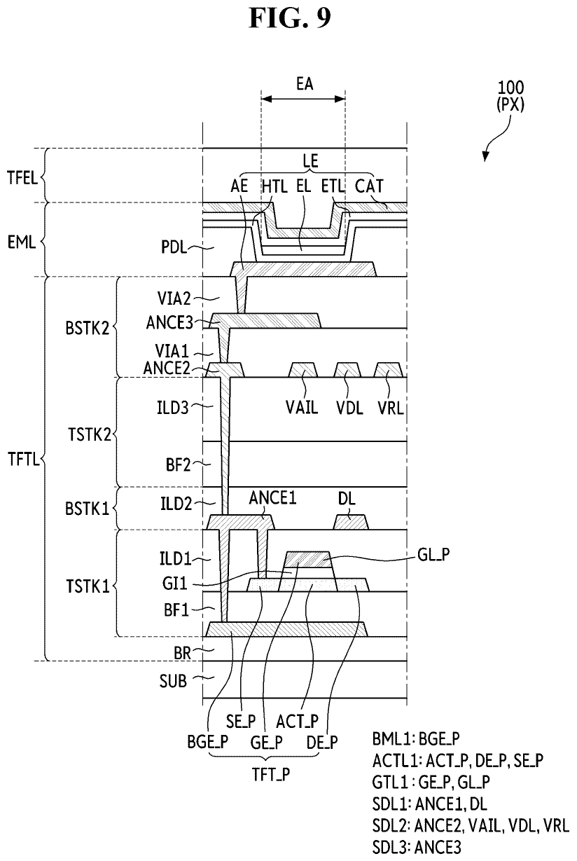

The element layer EML may include light-emitting elements LE (see FIG. 7) respectively disposed in light-emitting areas EA (see FIG. 6) and light-receiving elements PD (see FIG. 9) respectively disposed in sensing areas PDA (see FIG. 6).

The circuit layer TFTL may include light-emitting pixel drivers EPD (see FIG. 7) electrically connected to the light-emitting elements LE (see FIG. 7) of the element layer EML, respectively, and sensing pixel drivers OPD (see FIG. 9) electrically connected to the light-receiving elements PD (see FIG. 9) of the element layer EML, respectively.

The encapsulation layer TFEL may be disposed on the element layer EML and have a structure in which at least one organic film is interposed between two or more inorganic films.

The touch sensor layer SENL may include touch electrodes for detecting a signal that varies in response to a touch of a person or an object, and sensing a point in the main area MA at which a touch of a person or an object occurs.

The polarization layer POL blocks external light reflected from the touch sensor layer SENL, the encapsulation layer TFEL, the element layer EML, the circuit layer TFTL, and interfaces therebetween, thereby preventing a decrease in visibility of an image due to external light reflection.

According to embodiments, the display device 10 may further include the display driving circuit 200 embodied as an IC and mounted on the sub-area SBA.

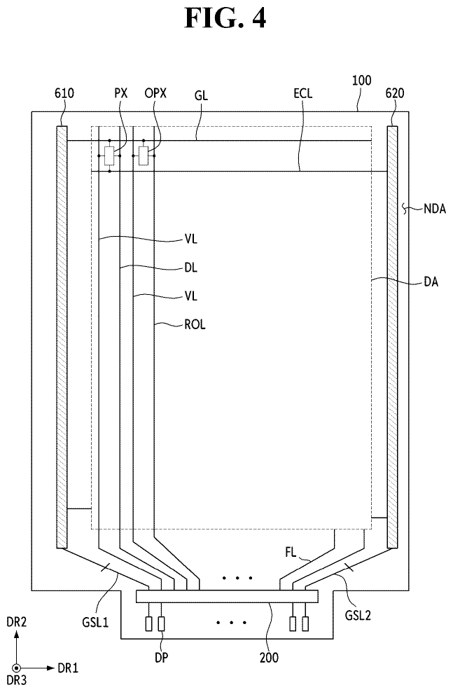

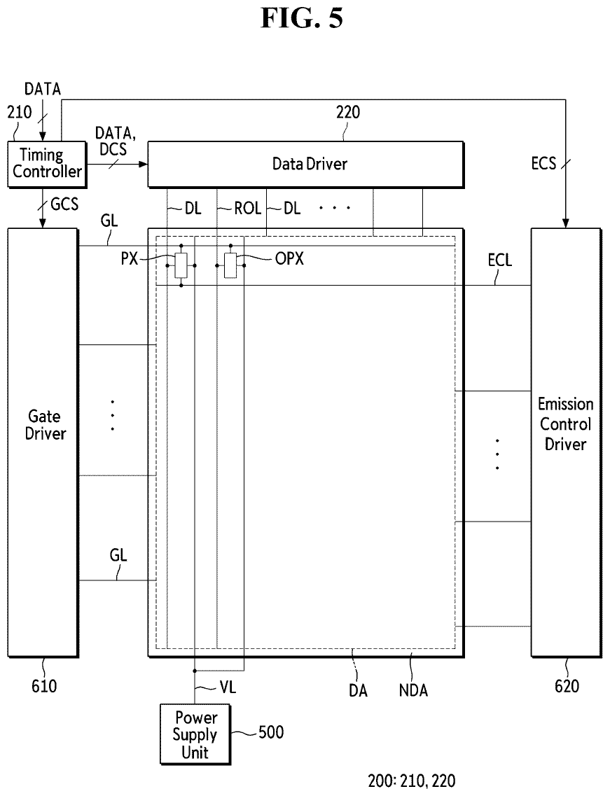

The display driving circuit 200 may supply digital video data DATA (see FIG. 5) to a data line DL (see FIG. 4) of the circuit layer TFTL.

According to embodiments, the display device 10 may further include the circuit board 300 mounted on the sub-area SBA. The circuit board 300 may be bonded to pads disposed in the sub-area SBA using an anisotropic conductive film or the like.

According to embodiments, the display device 10 may further include the touch driving circuit 400 mounted on the circuit board 300. When the touch sensor layer SENL includes capacitive touch electrodes and sensing electrodes, the touch driving circuit 400 may sense a touch based on whether capacitance is changed. However, this is merely an example, and the touch sensor layer SENL and the touch driving circuit 400 of FIG. 3 may be implemented in a touch sensing manner other than a capacitive manner.

FIG. 4 is a plan view illustrating a light-emitting pixel, a sensing pixel, various drivers, and various lines of a display device according to an embodiment. FIG. 5 is a block diagram illustrating a light-emitting pixel, a sensing pixel, various driving units, and various lines of a display device according to an embodiment.

Referring to FIGS. 4 and 5, the display panel 100 may include the display area DA and the non-display area NDA. The display area DA may include a light-emitting pixel PX, a sensing pixel OPX, a power line VL, a data line DL, a read-out line ROL, a gate line GL, and a light-emission control line ECL.

Each of the plurality of light-emitting pixels PX may be connected to the gate line GL, the light-emission control line ECL, the data line DL, and the power line VL. Each of the plurality of light-emitting pixels PX may include a plurality of transistors, a light-emitting element, and a capacitor.

Each of the plurality of sensing pixels OPX may be connected to the gate line GL, the power line VL, and the read-out line ROL. Each of the plurality of sensing pixels OPX may include a plurality of transistors and a light-receiving element.

The gate lines GL may extend in the first direction DR1 and may be spaced apart from each other in the second direction DR2 intersecting the first direction DR1. The gate lines GL may sequentially supply a gate signal to the light-emitting pixels PX and the sensing pixels OPX.

The light-emission control lines ECL may extend in the first direction DR1 and may be spaced apart from each other in the second direction DR2. The light-emission control lines ECL may sequentially supply a light-emission control signal to the light-emitting pixels PX.

The data lines DL may extend in the second direction DR2 and may be spaced apart from each other in the first direction DR1. The data lines DL may supply a data voltage to the light-emitting pixels PX. The data voltage may determine luminance of each of the light-emitting pixels PX.

The power lines VL may extend in the second direction DR2 and be spaced apart from each other in the first direction DR1. The power line VL may supply a power voltage to the light-emitting pixels PX and the sensing pixels OPX. In this regard, the power voltage may be a driving voltage, a common voltage, an initialization voltage, a reference voltage, a bias voltage, or a reset voltage. The driving voltage may be a high potential voltage for driving the light-emitting pixel PX, and the common voltage may be a low potential voltage for driving the light-emitting pixel PX and the sensing pixel OPX.

The non-display area NDA may surround the display area DA. The non-display area NDA may include a gate driver 610, a light-emission control driver 620, fan-out lines FL, a first gate control line GSL1, and a second gate control line GSL2.

The fan-out lines FL may extend from the display driving circuit 200 to the display area DA. The fan-out lines FL may supply the data voltage received from the display driving circuit 200 to the data line DL, may supply the power voltage received from the display driving circuit 200 to the power line VL, and may supply a sensing signal received from the read-out line ROL to the display driving circuit 200. Accordingly, the display driving circuit 200 may drive the light-emitting pixel PX and the sensing pixel OPX.

The first gate control line GSL1 may extend from the display driving circuit 200 to the gate driver 610. The first gate control line GSL1 may supply a gate control signal GCS received from the display driving circuit 200 to the gate driver 610.

The second gate control line GSL2 may extend from the display driving circuit 200 to the light-emission control driver 620. The second gate control line GSL2 may supply a light-emission control signal ECS received from the display driving circuit 200 to the light-emission control driver 620.

The sub-area SBA may extend from one side of the non-display area NDA. The sub-area SBA may include the display driving circuit 200 and a pad DP. The pad DP may be disposed closer to one side edge of the sub-area SBA than the display driving circuit 200 may be. The pad DP may be electrically connected to the circuit board 300 via an anisotropic conductive film (ACF).

The display driving circuit 200 may include a timing controller 210 and a data driver 220.

The timing controller 210 may receive the digital video data DATA and timing signals from the circuit board 300. The timing controller 210 may generate the data control signal DCS based on the timing signals, and may control an operation timing of the data driver 220 by supplying the digital video data DATA and the data control signal DCS to the data driver 220. The timing controller 210 may generate the gate control signal GCS and supply the gate control signal GCS to the gate driver 610, and may control an operation timing of the gate driver 610. The timing controller 210 may generate the light-emission control signal ECS and supply the light-emission control signal ECS to the light-emission control driver 620, and may control an operation timing of the light-emission control driver 620.

The data driver 220 may convert the digital video data DATA into analog data voltages and supply the analog data voltages to the data lines DL via the fan-out lines FL. The gate signals of the gate driver 610 may select the light-emitting pixels PX to which the data voltage is to be supplied, and the selected light-emitting pixels PX may receive the data voltage via the data lines DL. The data driver 220 may supply the sensing signal received via the read-out line ROL to a main processor.

A power supply 500 may be disposed on the circuit board 300 and be configured to supply the power voltage to the display driving circuit 200 and the display panel 100. The power supply 500 may generate the power voltage and supply the power voltage to the power line VL, and may generate the common voltage and supply the common voltage to a common electrode common to the light-emitting pixels PX and the sensing pixels OPX. The power supply 500 may generate the initialization voltage and supply the initialization voltage to the initialization voltage line, generate the reference voltage and supply the reference voltage to the reference voltage line, generate the bias voltage and supply the bias voltage to the bias voltage line, and generate the reset voltage and supply the reset voltage to the reset voltage line.

The gate driver 610 may be disposed outwardly of one side of the display area DA or at one side of the non-display area NDA, and the light-emission control driver 620 may be disposed outwardly of the other side of the display area DA or at the other side of the non-display area NDA. However, embodiments of the present disclosure are not limited thereto. In another example, the gate driver 610 and the light-emission control driver 620 may be disposed at one of one side and the other side of the non-display area NDA.

The gate driver 610 may include a plurality of transistors that generate gate signals based on the gate control signal GCS. The light-emission control driver 620 may include a plurality of transistors that generate light-emission signals based on the light-emission control signal ECS. For example, the transistors of the gate driver 610 and the transistors of the light-emission control driver 620 may be formed in the same layer as a layer in which the transistors of each of the light-emitting pixels PX is formed. The gate driver 610 may supply the gate signals to the gate lines GL, and the light light-emission control driver 620 may supply the light emission-control signals to the light light-emission control lines ECL.

FIG. 6 is a plan view illustrating a display area of a display device according to an embodiment.

Referring to FIG. 6, the display area DA may include light-emitting areas EA and non-light-emitting areas NEA.

The light-emitting areas EA may emit light of the light-emitting elements LE (see FIG. 7), and the light-emitting elements LE (see FIG. 7) may not be disposed in the non-light-emitting area NEA. The non-light-emitting area NEA may be an area other than the light-emitting area EA.

The light-emitting areas EA may include first to third light-emitting areas EA1, EA2, and EA3. For example, the first light-emitting area EA1 may emit light of a first color or red light, the second light-emitting area EA2 may emit light of a second color or green light, and the third light-emitting area EA3 may emit light of a third color or blue light. However, embodiments of the present disclosure are not limited thereto.

One light-emitting pixel PX may include one first light-emitting area EA1, one second light-emitting area EA2, and one third light-emitting area EA3 to express a white grayscale. However, a configuration of the light-emitting pixel PX is not limited thereto. The white grayscale may be expressed using a combination of light emitted from one first light-emitting area EA1, light emitted from one second light-emitting area EA2, and light emitted from one third light-emitting area EA3.

Area sizes of the first to third light-emitting areas EA1, EA2, and EA3 may be different from each other. For example, the area size of the third light-emitting area EA3 may be greater than the area size of the second light-emitting area EA2, and the area size of the second light-emitting area EA2 may be greater than the area size of the first light-emitting area EA1. However, embodiments of the disclosure are not limited thereto. In another example, the area sizes of the first to third light-emitting areas EA1, EA2, and EA3 may be equal to each other.

The display area DA may further include sensing areas PDA. The sensing areas PDA may be disposed in the non-light-emitting area NEA. The sensing areas PDA may be spaced apart from each other while at least one light-emitting area EA is interposed therebetween.

The sensing area PDA may be surrounded with the first to third light-emitting areas EA1, EA2, and EA3. The sensing area PDA may be disposed between the first light-emitting areas EA1 in a diagonal direction defined by the first direction DR1 and the second direction DR2, may be disposed between the second light-emitting areas EA2 in the first direction DR1, and may be disposed between the third light-emitting areas EA3 in the second direction DR2.

The sensing pixel OPX may receive light incident on the sensing area PDA.

FIG. 7 is an equivalent circuit diagram illustrating a light-emitting pixel according to an embodiment.

Referring to FIG. 7, the light-emitting pixel PX may be connected to a scan writing line GWL for transmitting a scan writing signal GW to the light-emitting pixel driver EPD, a reset control line GRL for transmitting a reset control signal GR to the light-emitting pixel driver EPD, a bias control line GBL for transmitting a bias control signal GB to the light-emitting pixel driver EPD, a first light-emission control line ECL1 for transmitting a first light-emission control signal EC1 to the light-emitting pixel driver EPD, a second light-emission control line ECL2 for transmitting a second light-emission control signal EC2 to the light-emitting pixel driver EPD, a first power line VDL for transmitting a first power ELVDD to the light-emitting pixel driver EPD, a second power line VSL for transmitting a second power ELVSS to the light-emitting pixel driver EPD, a reference voltage line VRL for transmitting a reference voltage VREF to the light-emitting pixel driver EPD, an initialization voltage line VAIL for transmitting an initialization voltage VINT to the light-emitting pixel driver EPD, and the data line DL for transmitting the digital video data DATA to the light-emitting pixel driver EPD.

The light-emitting pixel PX may include the light-emitting element LE and the light-emitting pixel driver EPD for driving the light-emitting element LE.

The light-emitting elements LE may be disposed between and electrically connected to the light-emitting pixel drivers EPD and the second power line VSL. One light-emitting element LE among the light-emitting elements LE may be disposed between and electrically connected to one light-emitting pixel driver EPD among the light-emitting pixel drivers EPD and the second power line VSL.

The second power ELVSS may have a voltage level lower than that of the first power ELVDD. An anode electrode of the light-emitting element LE may be electrically connected to the light-emitting pixel driver EPD, and the second power ELVSS having a voltage level lower than that of the first power ELVDD may be applied to a cathode electrode of the light-emitting element LE.

A light-emitting capacitor Cel connected in parallel with the light-emitting element LE has a parasitic capacitance between the anode electrode and the cathode electrode.

The light-emitting pixel driver EPD may include a first transistor T1 that generates a driving current for driving the light-emitting element LE, two or more transistors T2 to T6 electrically connected to the first transistor T1, and one or more capacitors C1 and C2.

A second transistor T2 may be disposed between and electrically connected to a gate electrode of the first transistor T1 and the data line DL. The second transistor T2 may be turned on based on the scan write signal GW of the scan write line GWL. When the second transistor T2 is turned on, the digital video data DATA of the data line DL may be transmitted to the gate electrode of the first transistor T1.

When a voltage difference between a voltage of the gate electrode of the first transistor T1 and a voltage of a second electrode (e.g., a source electrode) of the first transistor T1 becomes equal to or greater than a threshold voltage of the first transistor T1, based on the digital video data DATA applied to the gate electrode of the first transistor T1, the first transistor T1 may be turned on. Accordingly, a drain-source current of the first transistor T1 may be generated to have a magnitude corresponding to the digital video data DATA.

A third transistor T3 may be disposed between and electrically connected to the gate electrode of the first transistor T1 and the reference voltage line VRL. The third transistor T3 may be turned on based on the reset control signal GR of the reset control line GRL. When the third transistor T3 is turned on, a potential of the gate electrode of the first transistor T1 may be reset to the reference voltage VREF of the reference voltage line VRL.

A fourth transistor T4 may be disposed between and electrically connected to the light-emitting element LE and the initialization voltage line VAIL. The fourth transistor T4 may be turned on based on the bias control signal GB of the bias control line GBL. When the fourth transistor T4 is turned on, a potential of the anode electrode of the light-emitting element LE may be initialized to the initialization voltage VINT of the initialization voltage line VAIL.

A fifth transistor T5 may be disposed between and electrically connected to the first electrode (e.g., the drain electrode) of the first transistor T1 and the first power line VDL. The fifth transistor T5 may be turned on based on the first light-emission control signal EC1 of the first light-emission control line ECL1. When the fifth transistor T5 is turned on, the first power ELVDD of the first power line VDL may be transmitted to the first electrode of the first transistor T1.

A sixth transistor T6 may be disposed between and electrically connected to the second electrode (e.g., the source electrode) of the first transistor T1 and the light-emitting element LE. The sixth transistor T6 may be turned on based on the second light-emission control signal EC2 of the second light-emission control line ECL2. When the sixth transistor T6 is turned on, the drain-source current of the first transistor T1 which has been generated to have the magnitude corresponding to the digital video data DATA may be transmitted to the light-emitting element LE via the sixth transistor T6. Accordingly, the light-emitting element LE may emit light having a luminance level corresponding to the digital video data DATA.

The first capacitor C1 may be disposed between and electrically connected to the gate electrode of the first transistor T1 and the second electrode (e.g., the source electrode) of the first transistor T1.

Accordingly, the first capacitor C1 may be filled with the digital video data DATA applied to the gate electrode of the first transistor T1, and the turned-on state of the first transistor T1 may be maintained for a predetermined period due to the voltage filling the first capacitor C1.

The second capacitor C2 may be disposed between and electrically connected to the second electrode (e.g., the source electrode) of the first transistor T1 and the first power line VDL.

A voltage across the first capacitor C1 may correspond to a potential difference between a potential of the gate electrode of the first transistor T1 and a potential of the second electrode (e.g., the source electrode) of the first transistor T1 and may be varied based on the digital video data DATA and may be redistributed across the second capacitor C2. Accordingly, the threshold voltage of the first transistor T1 may be compensated for, and a variation in the threshold voltage of the first transistor T1 may be compensated for to realize a stable operation.

In an embodiment, as illustrated in FIG. 7, each of the first to sixth transistors T1 to T6 may be embodied as an N-type metal-oxide-semiconductor (MOS) field effect transistor (FET) (MOSFET) (NMOSFET). However, embodiments of the present disclosure are not limited thereto, and at least one of the first to sixth transistors T1 to T6 may be embodied as a P-type MOSFET (PMOSFET).

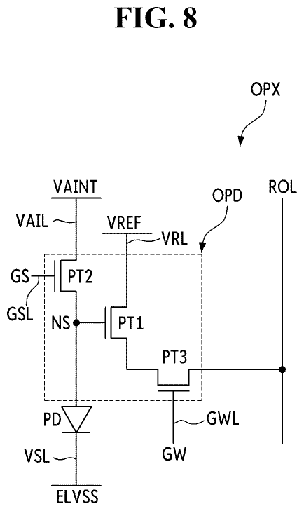

FIG. 8 is an equivalent circuit diagram illustrating a sensing pixel according to an embodiment.

Referring to FIG. 8, the sensing pixel OPX may be connected to the reset signal line GSL for transmitting the reset signal GS to the sensing pixel driver OPD, the scan write line GWL for transmitting the scan write signal GW to the sensing pixel driver OPD, the second power line VSL for transmitting the second power ELVSS to the sensing pixel driver OPD, the reference voltage line VRL for transmitting the reference voltage VREF to the sensing pixel driver OPD, and the initialization voltage line VAIL for transmitting the initialization voltage VINT to the sensing pixel driver OPD.

The sensing pixel OPX may include a light-receiving element PD and the sensing pixel driver OPD for driving the light-receiving element PD.

The light-receiving elements PD may be disposed between and electrically connected to the sensing pixel drivers OPD and the second power line VSL. One light-receiving element PD among the light-receiving elements PD may be disposed between and electrically connected to one sensing pixel driver OPD among the sensing pixel drivers OPD and the second power line VSL.

The second power ELVSS may have a voltage level lower than that of each of the initialization voltage VINT and the reference voltage VREF. An anode electrode of the light-receiving element PD may be electrically connected to the sensing pixel driver OPD, and the second power ELVSS may be applied to a cathode electrode of the light-receiving element PD.

The sensing pixel driver OPD may include first to third sensor transistors PT1, PT2, and PT3.

The first sensor transistor PT1 may include a gate electrode, a first electrode, and a second electrode. The gate electrode of the first sensor transistor PT1 may be connected to a sensor node NS, the first electrode thereof may be connected to the third sensor transistor PT3, and the second electrode thereof may be connected to the reference voltage line VRL. The first sensor transistor PT1 may control a source-drain current Isd (hereinafter referred to as a “sensing current”) based on a voltage of the sensor node NS as the first electrode of the light-receiving element PD. The sensing current flowing through a channel of the first sensor transistor PT1 may be proportional to a square of a difference between a voltage Vsg between the source electrode and the gate electrode of the first sensor transistor PT1 and a threshold voltage Vth thereof (Isd=k′×(Vsg−Vth)²). In this regard, k′ is a proportional coefficient determined by the structure and physical characteristics of the first sensor transistor PT1, Vsg is the source-gate voltage of the first sensor transistor PT1, and Vth is a threshold voltage of the first sensor transistor PT1. The first electrode of the first sensor transistor PT1 may be a source electrode and the second electrode may be a drain electrode. However, embodiments of the present disclosure is not limited thereto.

The second sensor transistor PT2 may be turned on based on the reset signal GS of the reset signal line GSL to discharge the voltage of the sensor node NS to the reset voltage. A gate electrode of the second sensor transistor PT2 may be connected to the reset signal line GSL, a first electrode thereof may be connected to the sensor node NS, and a second electrode thereof may be connected to the initialization voltage line VAIL. The first electrode of the second sensor transistor PT2 may be connected to the first electrode of the light-receiving element PD and the gate electrode of the first sensor transistor PT1 via the sensor node NS. The first electrode of the second sensor transistor PT2 may be a drain electrode and the second electrode may be a source electrode. However, embodiments of the present disclosure are not limited thereto.

The third sensor transistor PT3 may be turned on based on the scan write signal GW of the scan write line GWL to electrically connect the first electrode of the first sensor transistor PT1 and the read-out line ROL to each other.

The light-receiving element PD may receive light and convert light energy into an electrical signal. The first electrode of the light-receiving element PD may be connected to the sensor node NS as the gate electrode of the first sensor transistor PT1, and the second electrode thereof may be connected to the second power line VSL. The second electrode of the light-receiving element PD may receive the second power ELVSS from the second power line VSL. For example, the first electrode of the light-receiving element PD may be a sensor electrode and the second electrode thereof may be a common electrode. However, embodiments of the present disclosure are not limited thereto.

When the object is positioned on the display panel 100, light emitted from the light-emitting element LE may be reflected to the object, and the light-receiving element PD may receive the reflected light. The light-receiving element PD may convert the energy of light into an electrical signal (current or voltage) generated between the first electrode and the second electrode, and the converted electrical signal may flow from the second power line VSL to the sensor node NS as a reverse bias current. For example, when the light-receiving element PD receives light such that an electric field is generated between the first electrode and the second electrode of the light-receiving element PD, a current may flow through the light-receiving element PD in proportion to the amount of light, and a voltage of the sensor node NS may increase. Accordingly, when the light-receiving element PD receives light, the voltage of the sensor node NS may increase, and the magnitude of the sensing current (or source-drain current) of the first sensor transistor PT1 may decrease. The sensing current of the first sensor transistor PT1 as a sensing signal may be applied to the display driving circuit 200 through the third sensor transistor PT3 and the read-out line ROL.

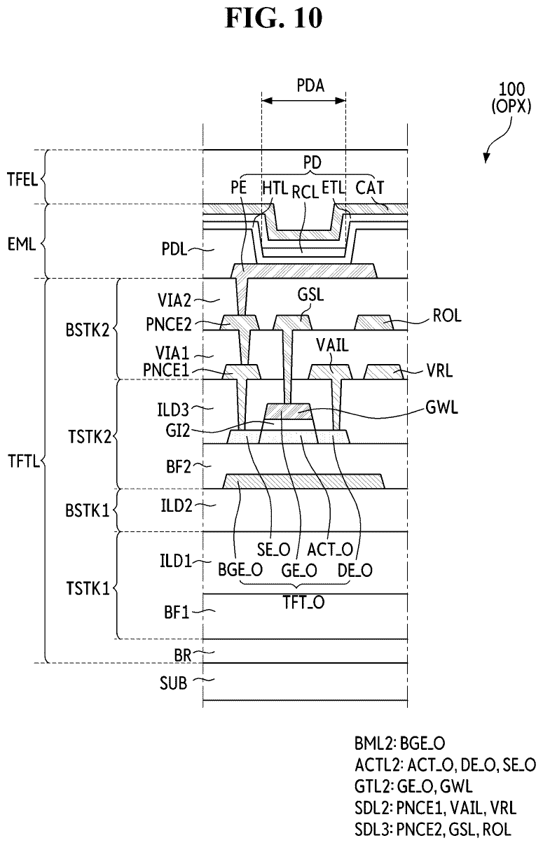

FIG. 9 is a cross-sectional view illustrating a light-emitting pixel according to an embodiment. FIG. 10 is a cross-sectional view illustrating a sensing pixel according to an embodiment.

Referring to FIGS. 9 and 10 in addition to FIGS. 7 and 8, the display panel 100 may include the substrate SUB, the circuit layer TFTL, and the element layer EML.

The light-emitting pixel PX may include the light-emitting pixel driver EPD and the light-emitting element LE. The light-emitting pixel driver EPD may include a light-emission transistor TFT_P, and the light-emission transistor TFT_P may be disposed in the circuit layer TFTL. The light-emission transistor TFT_P may include the first to sixth transistors T1 to T6 as described with reference to FIG. 7. The light-emitting element LE may be disposed in the element layer EML.

The sensing pixel OPX may include the sensing pixel driver OPD and the light-receiving element PD. The sensing pixel driver OPD may include a light-receiving transistor TFT_O, and the light-receiving transistor TFT_O may be disposed in the circuit layer TFTL. The light-receiving transistor TFT_O may include the first to third sensor transistors PT1, PT2, and PT3 as described with reference to FIG. 8. The light-receiving element PD may be disposed in the element layer EML.

The substrate SUB may be a base substrate or a base member. The substrate SUB may be a flexible substrate capable of bending, folding, rolling, and the like. For example, the substrate SUB may include a polymer resin such as polyimide. However, embodiments of the present disclosure are not limited thereto. For another example, the substrate SUB may include a glass material or a metal material.

The circuit layer TFTL may include a barrier layer BR, a first lower conductive layer BML1, a first buffer layer BF1, a first active layer ACTL1, a first gate insulating layer GI1, a first gate layer GTL1, a first interlayer insulating layer ILD1, a first source drain layer SDL1, a second interlayer insulating layer ILD2, a second lower conductive layer BML2, a second buffer layer BF2, a second active layer ACTL2, a second gate insulating layer GI2, a third interlayer insulating layer GTL3, a second source/drain layer SDL2, a first via layer VIA1, a third source/drain layer SDL3, and a second via layer VIA2.

The barrier layer BR may be a film for protecting the transistors of the circuit layer TFTL and the light-emitting layer EL and the light-receiving layer RCL of the element layer EML from moisture extending through the substrate SUB that is vulnerable to moisture permeation. The barrier layer BR may be formed as a single-layered inorganic film or a plurality of alternately stacked inorganic films. For example, the barrier layer BR may include at least one of a silicon nitride layer, a silicon oxynitride layer, a silicon oxide layer, a titanium oxide layer, and an aluminum oxide layer.

The first lower conductive layer BML1 may be disposed on the barrier layer BR. The first lower conductive layer BML1 may be disposed to be overlapped by a semiconductor area ACT_P of the light-emission transistor TFT_P in the third direction DR3 in order to prevent a leakage current from occurring due to light incident on the semiconductor area ACT_P of the light-emission transistor TFT_P. The first lower conductive layer BML1 may include a lower gate electrode BGE_P of the light-emission transistor TFT_P. Accordingly, the quality of the light-emission transistor TFT_P may be improved. The first lower conductive layer BML1 may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof.

The first buffer layer BF1 may be disposed on the first lower conductive layer BML1. The first buffer layer BF1 may prevent the penetration of air or moisture. The first buffer layer BF1 may include a single-layered inorganic film or a plurality of alternately stacked inorganic films. For example, the first buffer layer BF1 may include at least one of a silicon nitride layer, a silicon oxynitride layer, a silicon oxide layer, a titanium oxide layer, and an aluminum oxide layer.

The first active layer ACTL1 may be disposed on the first buffer layer BF1. The first active layer ACTL1 may include a semiconductor material. For example, the first active layer ACTL1 may include a silicon-based semiconductor material such as low temperature polycrystalline silicon (LTPS) or an oxide-based semiconductor material. The first active layer ACTL1 may include the semiconductor area ACT_P, the first electrode DE_P, and the second electrode SE_P of the light-emission transistor TFT_P.

The first gate insulating layer GI1 may be disposed on the first active layer ACTL1. The first gate insulating layer GI1 may insulate the first active layer ACTL1 and the first gate layer GTL1. The first gate insulating layer GI1 may include a single-layered inorganic film or a plurality of alternately stacked inorganic films. For example, the first gate insulating layer GI1 may include at least one of a silicon nitride layer, a silicon oxy nitride layer, a silicon oxide layer, a titanium oxide layer, and an aluminum oxide layer.

The first gate layer GTL1 may be disposed on the first gate insulating layer GI1. The first gate layer GTL1 may include a gate line GL_P and a gate electrode GE_P of the light-emission transistor TFT_P. The gate line GL_P may include the scan write line GWL, the reset control line GRL, the bias control line GBL, the first light-emission control line ECL1, and the second light-emission control line ECL2 as described with reference to FIG. 7. The gate electrode GE_P of the light-emission transistor TFT_P may be a portion of the gate line GL_P. The first gate layer GTL1 may be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

The first interlayer insulating layer ILD1 may be disposed on the first gate layer GTL1. The first interlayer insulating layer ILD1 may insulate the first gate layer GTL1 and the first source/drain layer SDL1 from each other. The first interlayer insulating layer ILD1 may include a single-layered inorganic film or a plurality of alternately stacked inorganic films. For example, the first interlayer insulating layer ILD1 may include at least one of a silicon nitride layer, a silicon oxy nitride layer, a silicon oxide layer, a titanium oxide layer, and an aluminum oxide layer.

The first source/drain layer SDL1 may be disposed on the first interlayer insulating layer ILD1. The first source/drain layer SDL1 may include a first anode connection electrode ANCE1 and the data line DL. When the light-emission transistor TFT_P is the sixth transistor T6, the first anode connection electrode ANCE1 may electrically connect the second electrode SE_P of the light-emission transistor TFT_P and a second anode connection electrode ANCE2 to each other. When the light-emission transistor TFT_P is the second transistor T2, the data line DL may be electrically connected to the first electrode DE_P of the light-emission transistor TFT_P. The first source/drain layer SDL1 may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof.

The second interlayer insulating layer ILD2 may be disposed on the first source drain layer SDL1. The second interlayer insulating layer ILD2 may insulate the first source and drain layer SDL1 and the second lower conductive layer BML2. The second interlayer insulating layer ILD2 may include a single-layered inorganic film or a plurality of alternately stacked inorganic films. For example, the second interlayer insulating layer ILD2 may include at least one of a silicon nitride layer, a silicon oxy nitride layer, a silicon oxide layer, a titanium oxide layer, and an aluminum oxide layer.

The second lower conductive layer BML2 may be disposed on the second interlayer insulating layer ILD2. The second lower conductive layer BML2 may be disposed to be overlapped by a semiconductor area ACT_O of the light-receiving transistor TFT_O in the third direction DR3 to prevent leakage current from occurring due to light incident on the semiconductor area ACT_O of the light-receiving transistor TFT_O. The second lower conductive layer BML2 may include the lower gate electrode BGE_O of the light-receiving transistor TFT_O. Accordingly, the quality of the light-receiving transistor TFT_O may be improved. The second lower conductive layer BML2 may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof.

The second buffer layer BF2 may be disposed on the second lower conductive layer BML2. The second gate insulating layer GI2 may insulate the second lower conductive layer BML2 from the second active layer ACTL2. The second buffer layer BF2 may include a single-layered inorganic film or a plurality of alternately stacked inorganic films. For example, the second buffer layer BF2 may include at least one of a silicon nitride layer, a silicon oxy nitride layer, a silicon oxide layer, a titanium oxide layer, and an aluminum oxide layer.

The second active layer ACTL2 may be disposed on the second buffer layer BF2. The second active layer ACTL2 may include a semiconductor material. For example, the second active layer ACTL2 may include a silicon-based semiconductor material such as low temperature polycrystalline silicon (LTPS) or an oxide-based semiconductor material. The second active layer ACTL2 may include the semiconductor area ACT_O, the first electrode DE_O, and the second electrode SE_O of the light-receiving transistor TFT_O.

The second gate insulating layer GI2 may be disposed on the second active layer ACTL2. The second gate insulating layer GI2 may insulate the second active layer ACTL2 and a second gate layer GTL2 from each other. The second gate insulating layer GI2 may include a single-layered inorganic film or a plurality of alternately stacked inorganic films. For example, the second gate insulating layer GI2 may include at least one of a silicon nitride layer, a silicon oxy nitride layer, a silicon oxide layer, a titanium oxide layer, and an aluminum oxide layer.

The second gate layer GTL2 may be disposed on the second gate insulating layer GI2. The second gate layer GTL2 may include the scan write line GWL and the gate electrode GE_O of the light-receiving transistor TFT_O. When the light-receiving transistor TFT_O is the third sensor transistor PT3, the gate electrode GE_O of the light-receiving transistor TFT_O may be a portion of the scan write line GWL, or may be electrically connected to the scan write line GWL. The second gate layer GTL2 may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof.

The third interlayer insulating layer ILD3 may be disposed on the second gate layer GTL2. The third interlayer insulating layer ILD3 may insulate the second gate layer GTL2 and the second source/drain layer SDL2 from each other. The third interlayer insulating layer ILD3 may include a single-layered inorganic film or a plurality of alternately stacked inorganic films. For example, the third interlayer insulating layer ILD3 may include at least one of a silicon nitride layer, a silicon oxy nitride layer, a silicon oxide layer, a titanium oxide layer, and an aluminum oxide layer.

The second source/drain layer SDL2 may be disposed on the third interlayer insulating layer ILD3. The second source/drain layer SDL2 may include the second anode connection electrode ANCE2, the initialization voltage line VAIL, the first power line VDL, and the reference voltage line VRL in the light-emitting pixel PX, and may include the first sensor connection electrode PNCE1, the initialization voltage line VAIL, and the reference voltage line VRL in the sensing pixel OPX. The second source/drain layer SDL2 may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof.

When the light-emission transistor TFT_P is the sixth transistor T6, the second anode connection electrode ANCE2 may electrically connect the first anode connection electrode ANCE1 and the third anode connection electrode ANCE3 to each other. When the light-emission transistor TFT_P is the third transistor T3, the reference voltage line VRL may be electrically connected to the first electrode DE_P of the light-emission transistor TFT_P. When the light-emission transistor TFT_P is the fourth transistor T4, the initialization voltage line VAIL may be electrically connected to the second electrode SE_P of the light-emission transistor TFT_P. When the light-emission transistor TFT_P is the fifth transistor T5, the first power line VDL may be electrically connected to the first electrode DE_P of the light-Emission transistor TFT_P.

When the light-receiving transistor TFT_O is the second sensor transistor PT2, the first sensor connection electrode PNCE1 may electrically connect the second electrode SE_O of the light-receiving transistor TFT_O to a second sensor connection electrode PNCE2. When the light-receiving transistor TFT_O is the second sensor transistor PT2, the initialization voltage line VAIL may be electrically connected to the first electrode DE_O of the light-receiving transistor TFT_O. When the light-receiving transistor TFT_O is the first sensor transistor PT1, the reference voltage line VRL may be electrically connected to the first electrode DE_O of the light-receiving transistor TFT_O.

The first via layer VIA1 may be disposed on the second source/drain layer SDL2. The first via layer VIA1 may insulate the second source/drain layer SDL2 from the third source/drain layer SDL3. An upper surface of the first via layer VIA1 may be flat. The first via layer VIA1 may include an organic insulating material such as polyimide.

The third source/drain layer SDL3 may be disposed on the first via layer VIA1. The third source/drain layer SDL3 may include a third anode connection electrode ANCE3 in the light-emitting pixel PX, and may include the second sensor connection electrode PNCE2, the reset signal line GSL, and the read-out line ROL in the sensing pixel OPX. The third source/drain layer SDL3 may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof.

When the light-emission transistor TFT_P is the sixth transistor T6, the third anode connection electrode ANCE3 may electrically connect the second anode connection electrode ANCE2 and the pixel electrode AE of the light-emitting element LE to each other.

When the light-receiving transistor TFT_O is the second sensor transistor PT2, the second sensor connection electrode PNCE2 may electrically connect the first sensor connection electrode PNCE1 and the sensor electrode PE of the light-receiving element PD to each other. When the light-receiving transistor TFT_O is the second sensor transistor PT2, the reset signal line GSL may be electrically connected to the gate electrode GE_O of the light-receiving transistor TFT_O. When the light-receiving transistor TFT_O is the third sensor transistor PT3, the read-out line ROL may be electrically connected to the second electrode SE_O of the light-receiving transistor TFT_O.

The second via layer VIA2 may be disposed on the third source/drain layer SDL3. The second via layer VIA2 may insulate the third source/drain layer SDL3 from the pixel electrode AE of the light-emitting element LE, and may insulate the third source/drain layer SDL3 from the sensor electrode PE of the light-emitting element LE. An upper surface of the second via layer VIA2 may be flat. The second via layer VIA2 may include an organic insulating material such as polyimide.

The element layer EML may include a pixel defining film PDL, the light-emitting element LE, and the light-receiving element PD.

The pixel defining film PDL may be disposed on the pixel electrode AE of the light-emitting element LE and the second via layer VIA2. The pixel defining film PDL may define each of the plurality of light-emitting areas EA. The pixel defining film PDL may include an organic insulating material such as polyimide. However, embodiments of the present disclosure are not limited thereto.

The light-emitting element LE may include a pixel electrode AE, a hole transport layer HTL, an emission layer EL, an electron transport layer ETL, and a common electrode CAT.

The pixel electrode AE may be disposed on the second via layer VIA2. The pixel electrode AE may be overlapped by each of the plurality of light-emitting areas EA defined by the pixel defining film PDL. The pixel electrode AE may receive a driving current from the light-emitting pixel driver EPD of the light-emitting pixel PX.

The hole transport layer HTL may be disposed on the pixel electrode AE in the light-emitting area EA, and may be disposed on the pixel defining film PDL in an area other than the light-emitting area EA. The hole transport layer HTL is not separate on each light-emitting pixel PX basis, and may be implemented as a common layer of all of the light-emitting pixels PX and the sensing pixels OPX.

The light-emitting layer EL may be disposed on the hole transport layer HTL in the light-emitting area EA. For example, the light-emitting layer EL may be an organic light-emitting layer made of an organic material. However, embodiments of the present disclosure are not limited thereto.

The electron transport layer ETL may be disposed on the emission layer EL in the light-emitting area EA, and may be disposed on the hole transport layer HTL in an area other than the light-emitting area EA. The electron transport layer ETL is not separate on each light-emitting pixel PX basis, and may be implemented as a common layer of all of the light-emitting pixels PX and the sensing pixels OPX.

The common electrode CAT may be disposed on the electron transport layer ETL. For example, the common electrode CAT may not be separate on each light-emitting pixel PX basis but be implemented in the form of an electrode common to all of the light-emitting pixels PX and the sensing pixels OPX. The common electrode CAT may be a transparent electrode and may transmit light therethrough. The common electrode CAT may be electrically connected to the second power line VSL, and may receive the second voltage ELVSS (or a low potential voltage, a common voltage, or a cathode voltage).

When the light-emitting layer EL is embodied as an organic light-emitting layer, the light-emitting pixel driver EPD of the light-emitting pixel PX may apply a predetermined voltage to the pixel electrode AE. When the common electrode CAT receives a common voltage or a cathode voltage, holes may migrate to the light-emitting layer EL via the hole transport layer HTL, electrons may migrate to the light-emitting layer EL via the electron transport layer ETL, and the holes and the electrons may be combined with each other in the light-emitting layer EL to emit light.

The light-receiving element PD may include a sensor electrode PE, the hole transport layer HTL, a light-receiving layer RCL, the electron transport layer ETL, and the common electrode CAT.

The sensor electrode PE may be disposed on the second via layer VIA2 and may be disposed on the same layer as that of the pixel electrode AE of the light-emitting element LE. The sensor electrode PE may be overlapped by each of the plurality of sensing areas PDA defined by the pixel defining film PDL.

The hole transport layer HTL may be disposed on the sensor electrode PE in the sensing area PDA, and may be disposed on the pixel defining film PDL in an area other than the sensing area PDA. The hole transport layer HTL is not separate on each sensing pixel OPX basis, and may be implemented as a common layer of all of the light-emitting pixels PX and the sensing pixels OPX.

The light-receiving layer RCL may be disposed on the hole transport layer HTL in the sensing area PDA. The light-receiving layer RCL may receive light emitted from the light-emitting area EA and reflected from the object, or may receive light introduced from the outside. Light emitted from the light-emitting element LE of the light-emitting area EA may be reflected from the object, and the reflected light may reach the light-receiving layer RCL. Alternatively, the light introduced from the outside may be reflected from the object and then may reach the light-receiving layer RCL.

The electron transport layer ETL may be disposed on the light-receiving layer RCL in the sensing area PDA and may be disposed on the hole transport layer HTL in an area other than the sensing area PDA. The electron transport layer ETL is not separate on each sensing pixel OPX, and may be implemented as a common layer of all of the light-emitting pixels PX and the sensing pixels OPX.

The common electrode CAT may be disposed on the electron transport layer ETL. For example, the common electrode CAT may not be separate on each sensing pixel OPX, but be implemented in the form of an electrode common to all of the light-emitting pixels PX and the sensing pixels OPX. The common electrode CAT may be a transparent electrode and may transmit light therethrough. The common electrode CAT may be electrically connected to the second power line VSL, and may receive the second voltage ELVSS (or a low potential voltage, a common voltage, or a cathode voltage).

When the light-receiving layer RCL is embodied as an organic light-receiving layer, the light-receiving element PD may convert energy of light into an electrical signal (current or voltage) generated between the sensor electrode PE and the common electrode CAT, and the converted electrical signal may flow to the sensor node NS of FIG. 8 as a reverse bias current. For example, when the light-receiving element PD receives light such that the electric field is generated between the sensor electrode PE and the common electrode CAT of the light-receiving element PD, a current may flow through the light-receiving element PD in a proportional manner to the amount of light.

The encapsulation layer TFEL may be disposed on the common electrode CAT and may cover the light-emitting element LE and the light-receiving element PD. The encapsulation layer TFEL may include at least one inorganic film to prevent oxygen or moisture from extending through into the light-emitting element LE and the light-receiving element PD. The encapsulation layer TFEL may include at least one organic film to protect the light-emitting element LE and the light-receiving element PD from foreign materials such as dust.

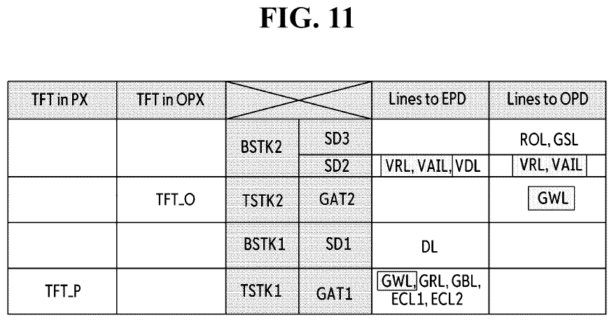

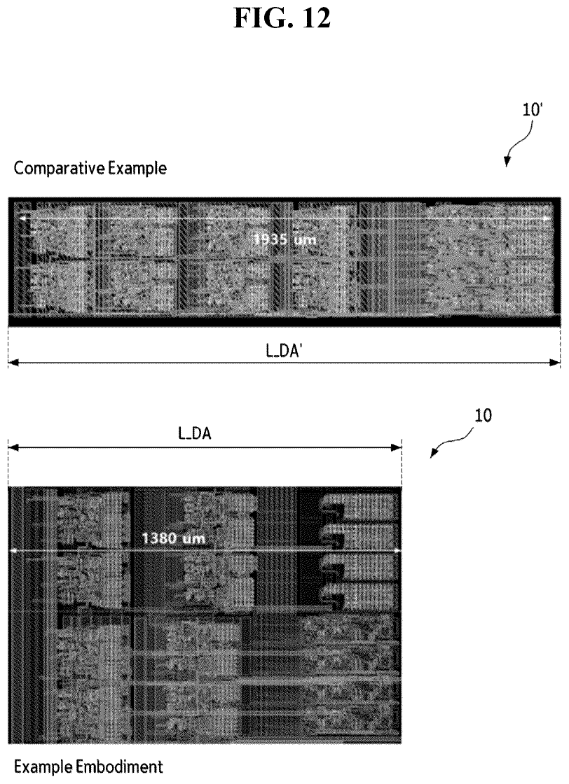

FIG. 11 is a table illustrating a layer-by-layer arrangement of lines connected to each of a light-emitting pixel and a sensing pixel and a layer-by-layer arrangement of transistors included in each of the light-emitting pixel and the sensing pixel of a display device according to an embodiment. FIG. 12 is a schematic layout diagram illustrating a display area of a display device according to each of comparative example and an embodiment.

Referring to FIGS. 11 and 12 in addition to FIGS. 9 and 10, in the display device 10 according to an embodiment, the circuit layer TFTL may include a first stack TSTK1, a first line stack BSTK1, a second stack TSTK2, and a second line stack BSTK2.

The first stack TSTK1 may be disposed on the substrate SUB (or the barrier layer BR). The first stack TSTK1 may include the first lower conductive layer BML1, the first buffer layer BF1, the first active layer ACTL1, the first gate insulating layer GI1, the first gate layer GTL1, and the first interlayer insulating layer ILD1. The first stack TSTK1 may include the light-emission transistor TFT_P. The first stack TSTK1 may include lines electrically connected to the light-emitting pixel driver EPD. For example, the first stack TSTK1 may include the scan write line GWL, the reset control line GRL, the bias control line GBL, the first light light-emission control line ECL1, and the second light light-emission control line ECL2.

The first line stack BSTK1 may be disposed on the first stack TSTK1. The first line stack BSTK1 may include the first source/drain layer SDL1 and the second interlayer insulating layer ILD2. The first line stack BSTK1 may include lines electrically connected to the light-emitting pixel driver EPD. For example, the first line stack BSTK1 may include the data line DL.

The second stack TSTK2 may be disposed on the first line stack BSTK1. The second stack TSTK2 may include the second lower conductive layer BML2, the second buffer layer BF2, the second active layer ACTL2, the second gate insulating layer GI2, the second gate layer GTL2, and the third interlayer insulating layer ILD3. The second stack TSTK2 may include the light-receiving transistor TFT_O. The second stack TSTK2 may include lines electrically connected to the sensing pixel driver OPD. For example, the second stack TSTK2 may include the scan write line GWL.

The second line stack BSTK2 may be disposed on the second stack TSTK2. The second line stack BSTK2 may include the second source/drain layer SDL2, the first via layer VIA1, the third source/drain layer SDL3, and the second via layer VIA2. The second line stack BSTK2 may include lines electrically connected to the light-emitting pixel driver EPD. For example, the second line stack BSTK2 may include the reference voltage line VRL, the initialization voltage line VAIL, and the first power line VDL. The second line stack BSTK2 may include lines electrically connected to the sensing pixel driver OPD. For example, the second stack TSTK2 may include the reference voltage line VRL, the initialization voltage line VAIL, the reset signal line GSL, and the read-out line ROL.

According to the display device 10 according to the example embodiment of the present disclosure, the number of light-emitting pixels PX and sensing pixels OPX disposed in the display area DA may be increased. That is, a high-resolution display device 10 may be provided.

For example, FIG. 12 is a view illustrating a portion of the display area DA including the same number of light-emitting pixels PX and sensing pixels OPX in each of a display device 10′ according to the comparative example and the display device 10 according to an example embodiment.

In the display device 10′ according to the comparative example, transistors of the light-emitting pixel driver EPD and transistors of the sensing pixel driver OPD may be disposed in one stack without distinction between the first stack TSTK1 and the second stack TSTK2. For example, the display device 10′ according to the comparative example may include the substrate SUB, a stack disposed on the substrate SUB and including the transistors of the light-emitting pixel driver EPD and the transistors of the sensing pixel driver OPD, and a line stack disposed on the stack.

The stack of the display device 10′ according to the comparative example may include the first lower conductive layer BML1, the first active layer ACTL1, and the first gate layer GTL1 which may be sequentially stacked. The line stack of the display device 10′ according to the comparative example may include at least one of the first to third source/drain layers SDL1, SDL2, and SDL3.

Unlike the display device 10 according to an example embodiment of the present disclosure, in the display device 10′ according to the comparative example, since both the light-emission transistors TFT_P of the light-emitting pixel driver EPD and the light-receiving transistors TFT_O of the sensing pixel driver OPD are disposed under the line stack without a stack distinction, an extra space in which the light-receiving transistors TFT_O are disposed is required between the light-emission transistors TFT_P.

For example, when the stack of the display device 10′ according to the comparative example includes the first lower conductive layer BML1, the first active layer ACTL1, and the first gate layer GTL1, the semiconductor area ACT_P of each of the light-emission transistors TFT_P and the semiconductor area ACT_O of each of the light-receiving transistors TFT_O are disposed in the same first active layer ACTL1, such that an extra space in which the light-receiving transistor TFT_O is disposed is further required between the light-emission transistors TFT_P.

Accordingly, as illustrated in FIG. 12, when a length of the display area DA including the same number of light-emitting pixels PX and sensing pixels OPX is referred to as a unit display length, the unit display length L_DA in the display device 10 according to the example embodiment of the present disclosure may be smaller than the unit display length L_DA′ in the display device 10′ according to the comparative example. Accordingly, the display device 10 according to the example embodiment may include a larger number of light-emitting pixels PX and sensing pixels OPX than the number of light-emitting pixels PX and sensing pixels OPX in the display device 10′ according to the comparative example in the display area DA having the same size.

Accordingly, in the display device 10 according to the example embodiment, the number of light-emitting pixels PX and sensing pixels OPX disposed in the display area DA may be increased. That is, a high-resolution display device 10 may be provided.

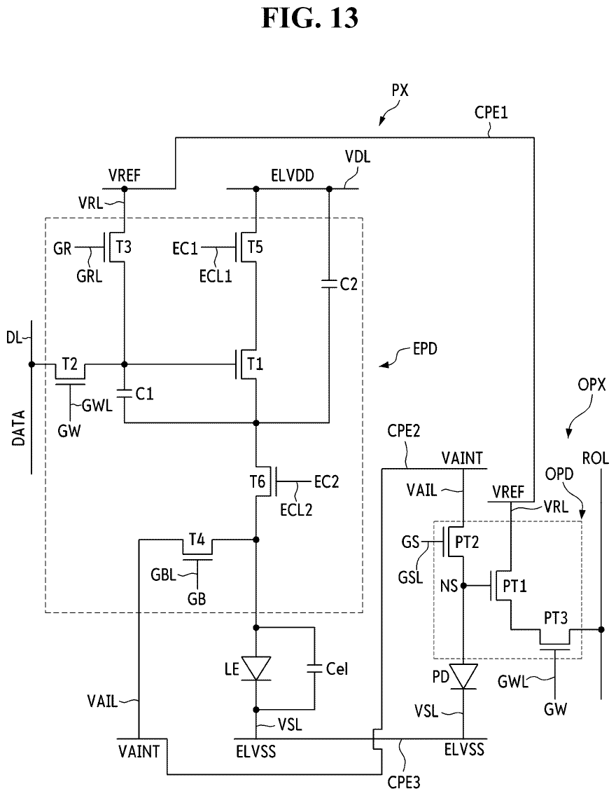

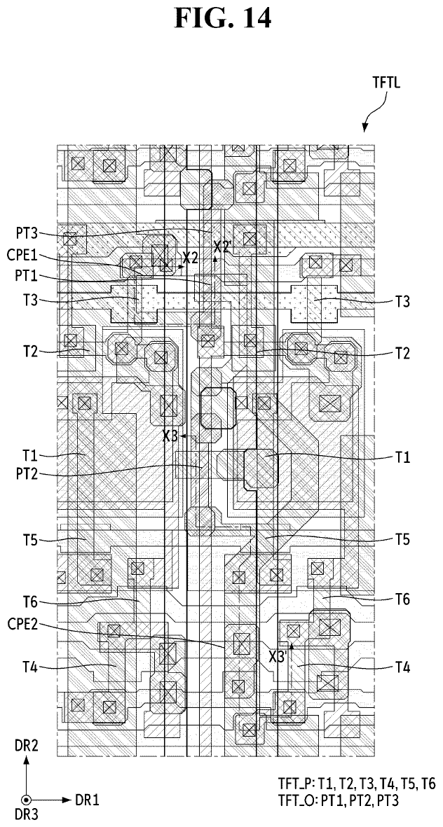

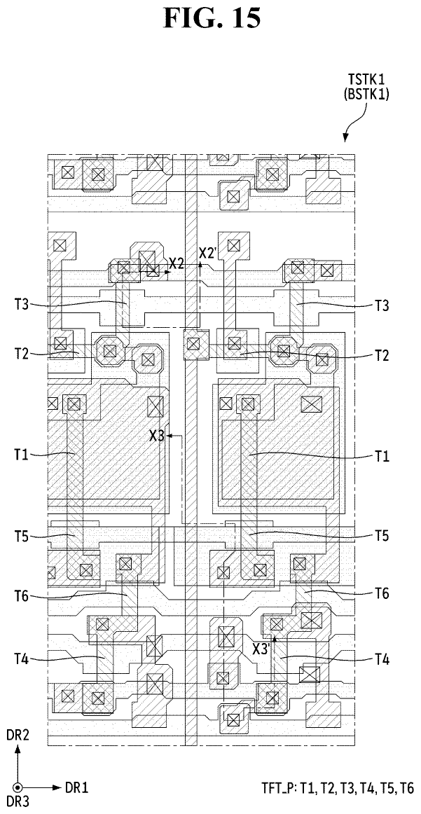

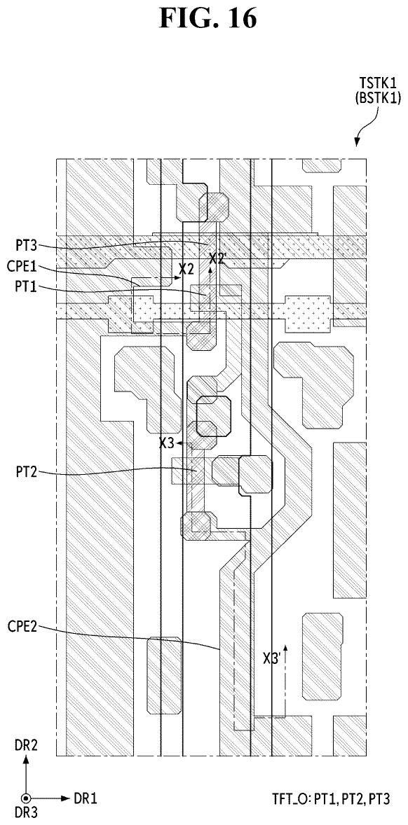

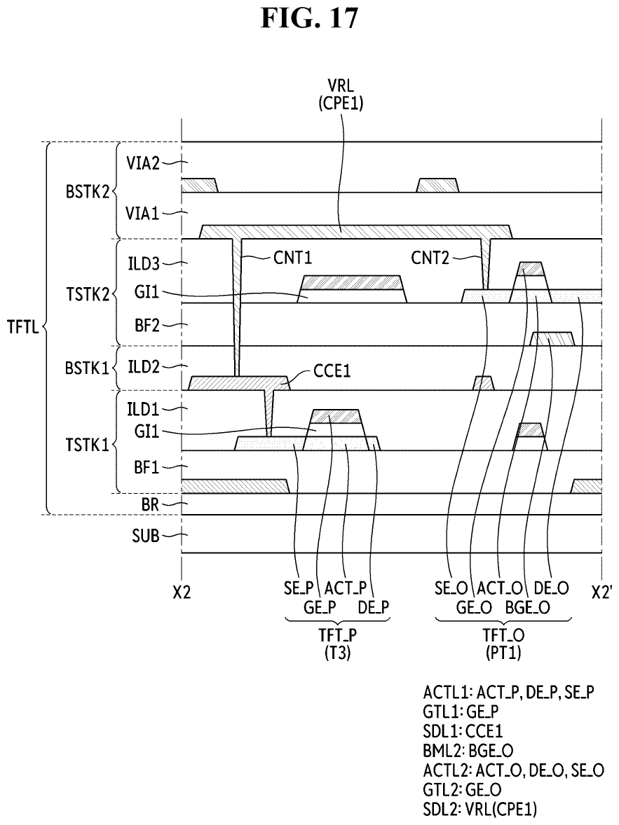

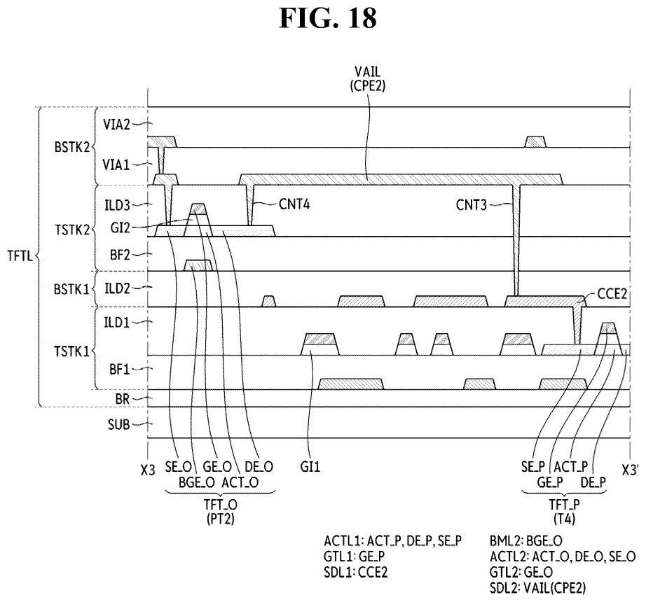

FIG. 13 is an equivalent circuit diagram illustrating connection portions connecting a light-emitting pixel, a sensing pixel, and a common application line to each other according to an embodiment. FIG. 14 is a layout diagram illustrating a portion of a display area DA according to an embodiment. FIG. 15 is a layout diagram illustrating a first stack and a first line stack according to an embodiment. FIG. 16 is a layout diagram illustrating a second stack and a second line stack according to an embodiment. FIG. 17 is a cross-sectional view taken along a line X2-X2′ of FIGS. 14 to 16 according to an embodiment. FIG. 18 is a cross-sectional view taken along a line X3-X3′ of FIGS. 14 to 16 according to an embodiment.

Referring to FIGS. 13 to 18 in addition to FIGS. 9 to 11, in the display device 10 according to an example embodiment of the present disclosure, the light-emitting pixel driver EPD and the light-emission transistor TFT_P of the light-emitting pixel driver EPD may be disposed in the first stack TSTK1, and the sensing pixel driver OPD and the light-receiving transistor TFT_O of the sensing pixel driver OPD may be disposed in the second stack TSTK2. In some embodiments, the light-emission transistor TFT_P of the light-emitting pixel driver EPD may include the first to sixth transistors T1 to T6, and the light-receiving transistor TFT_O of the sensing pixel driver OPD may include the first to third sensor transistors PT1 to PT3. However, the number of transistors of the light-emitting pixel driver EPD and the number of sensor transistors of the sensing pixel driver OPD are not limited thereto.

Since the light-emitting pixel driver EPD and the light-emission transistor TFT_P of the light-emitting pixel driver EPD, and the sensing pixel driver OPD and the light-receiving transistor TFT_O of the sensing pixel driver OPD are disposed in different stacks stacked on top of each other, the sensing pixel driver OPD and the light-receiving transistor TFT_O of the sensing pixel driver OPD may be at least partially overlapped by the light-emitting pixel driver EPD and the light-emission transistor TFT_P of the light-emitting pixel driver EPD in the third direction DR3. For example, as illustrated in FIGS. 14 to 16, the first sensor transistor PT1 may be overlapped by the second transistor T2 in the third direction DR3.

Since the light-emitting pixel driver EPD and the light-emission transistor TFT_P of the light-emitting pixel driver EPD, and the sensing pixel driver OPD and the light-receiving transistor TFT_O of the sensing pixel driver OPD are disposed in different stacks stacked on top of each other, the light-emitting pixel driver EPD and the light-emission transistor TFT_P of the light-emitting pixel driver EPD, and the sensing pixel driver OPD and the light-receiving transistor TFT_O of the sensing pixel driver OPD may not overlap each other.

In some embodiments, as illustrated in FIG. 13, each of the reference voltage line VRL, the initialization voltage line VAIL, the scan write line GWL, and the second power line ELVSS may be electrically connected to both the light-emitting pixel driver EPD and the sensing pixel driver OPD. A line electrically connected to both the light-emitting pixel driver EPD and the sensing pixel driver OPD may be referred to as a common application line.

The scan write line GWL acts as the common application line. However, as illustrated in FIGS. 11 and 13, the scan write line GWL may be disposed in each of the first stack TSTK1 and the second stack TSTK2 rather than the line stacks BSTK1 and BSTK2. For example, the scan writing line GWL connected to the light-emitting pixel driver EPD may be disposed in the first stack TSTK1, and the line connected to the sensing pixel driver OPD may be disposed in the second stack TSTK2. However, the present disclosure is not limited thereto. Like other common application lines, the scan writing line GWL may be commonly provided to the light-emitting pixel driver EPD and the sensing pixel driver OPD, and may be disposed in the second line stack BSTK2.

The common application line may include connection portions connecting one end adjacent to the light-emitting pixel driver EPD and the other end adjacent to the sensing pixel driver OPD to each other.

For example, the reference voltage line VRL may include a first connection portion CPE1 connecting one end adjacent to the light-emitting pixel driver EPD and the other end adjacent to the sensing pixel driver OPD to each other. The initialization voltage line VAIL may include a second connection portion CPE2 connecting one end adjacent to the light-emitting pixel driver EPD and the other end adjacent to the sensing pixel driver OPD to each other. The second power line ELVSS may include a third connection portion CPE3 connecting one end adjacent to the light-emitting pixel driver EPD and the other end adjacent to the sensing pixel driver OPD to each other. When the scan writing line GWL is provided in a common manner to the light-emitting pixel driver EPD and the sensing pixel driver OPD, the scan writing line GWL may include a fourth connection portion CPE4 connecting one end adjacent to the light-emitting pixel driver EPD to the other end adjacent to the sensing pixel driver OPD.

Referring to FIGS. 14 to 18, the first connection portion CPE1 and the second connection portion CPE2 will be described.

First, as illustrated in FIGS. 14 to 16 and 17, the reference voltage line VRL may be disposed in the second source/drain layer SDL2 of the second line stack BSTK2. The reference voltage line VRL may be electrically connected to the light-emission transistor TFT_P of the light-emitting pixel driver EPD and the light-receiving transistor TFT_O of the sensing pixel driver OPD.

For example, one end of the reference voltage line VRL may be electrically connected to the light-emission transistor TFT_P (e.g., the third transistor T3) via a first contact hole CNT1 and a first connection electrode CCE1. The first contact hole CNT1 may extend through the second interlayer insulating layer ILD2, the second buffer layer BF2, and the third interlayer insulating layer ILD3. The first connection electrode CCE1 may be disposed in the first source/drain layer SDL1.

The other end of the reference voltage line VRL may be electrically connected to the light-receiving transistor TFT_O (e.g., the first sensor transistor PT1) via a second contact hole CNT2. The second contact hole CNT2 may extend through the third interlayer insulating layer ILD3.

The reference voltage line VRL may include the first connection portion CPE1 connecting one end of the reference voltage line VRL adjacent to the light-emission transistor TFT_P to the other end of the reference voltage line VRL adjacent to the light-receiving transistor TFT_O. The first connection portion CPE1 may be disposed in the second source/drain layer SDL2. The first connection portion CPE1 may be disposed between the first contact hole CNT1 and the second contact hole CNT2.

Next, as illustrated in FIGS. 14 to 16 and 18, the initialization voltage line VAIL may be disposed in the second source drain layer SDL2 of the second line stack BSTK2. The initialization voltage line VAIL may be electrically connected to the light-emission transistor TFT_P of the light-emitting pixel driver EPD and the light-receiving transistor TFT_O of the sensing pixel driver OPD.

For example, one end of the initialization voltage line VAIL may be electrically connected to the light-emission transistor TFT_P (e.g., the fourth transistor T4) via a third contact hole CNT3 and a second connection electrode CCE2. The third contact hole CNT3 may extend through the second interlayer insulating layer ILD2, the second buffer layer BF2, and the third interlayer insulating layer ILD3. The second connection electrode CCE2 may be disposed in the first source/drain layer SDL1.

The other end of the initialization voltage line VAIL may be electrically connected to the light-receiving transistor TFT_O (e.g., the second sensor transistor PT2) via a fourth contact hole CNT4. The fourth contact hole CNT4 may extend through the third interlayer insulating layer ILD3.

The initialization voltage line VAIL may include the second connection portion CPE2 connecting one end of the initialization voltage line VAIL adjacent to the light-emission transistor TFT_P to the other end of the initialization voltage line VAIL adjacent to the light-receiving transistor TFT_O. The second connection portion CPE2 may be disposed in the second source/drain layer SDL2. The second connection portion CPE2 may be disposed between the third contact hole CNT3 and the fourth contact hole CNT4.

In the display device 10, the light-emitting pixel driver EPD and the light-emission transistor TFT_P of the light-emitting pixel driver EPD are disposed in the first stack TSTK1, and the sensing pixel driver OPD and the light-receiving transistor TFT_O of the sensing pixel driver OPD are disposed in the second stack TSTK2. Thus, the common application line commonly connected to the light-emitting pixel driver EPD and the light-emission transistor TFT_P of the light-emitting pixel driver EPD, and the sensing pixel driver OPD and the light-receiving transistor TFT_O of the sensing pixel driver OPD may be disposed in the second line stack BSTK2. In addition, each of the common application lines includes the connection portion, and the contact hole and the connection electrode connect the common application line to the light-emitting pixel driver EPD and the light-emission transistor TFT_P of the light-emitting pixel driver EPD, and the sensing pixel driver OPD and the light-receiving transistor TFT_O of the sensing pixel driver OPD. Thus, the common application line may be commonly connected to the light-emission transistor TFT_P of the light-emitting pixel driver EPD, the sensing pixel driver OPD, and the light-receiving transistor TFT_O of the sensing pixel driver OPD, despite the distinction between the first stack TSTK1 and the second stack TSTK2.

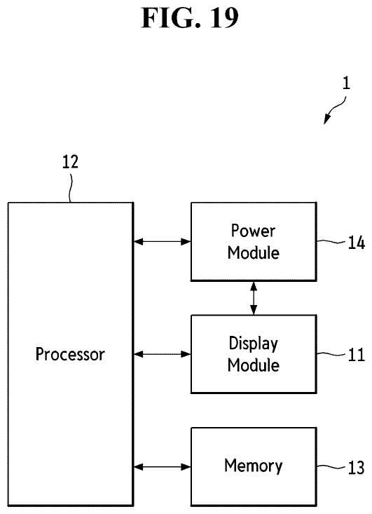

FIG. 19 is a block diagram of an electronic device according to an embodiment.

The display device 10 according to the above-described embodiments may be applied to various electronic devices 1. The electronic device 1 according to an embodiment may include the above-described display device 10, and may further include a module or a device having an additional function other than the display device 10.

Referring to FIG. 19, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for the operation of the processor 12 or the display module 11 may be stored in the memory 13. When the processor 12 executes an application stored in the memory 13, an image data signal and/or an input control signal may be transmitted to the display module 11, and the display module 11 may process the received signal to output image information on a display screen.

The power module 14 may include a power supply module such as a power adapter or a battery device, and a power conversion module that converts power supplied from the power supply module to generate power required for the operation of the electronic device 1.

At least one of the above-described components of the electronic device 1 may be included in the display device 10 according to the above-described embodiments. In addition, in a terms of a function, a portion of an individual module included in one module may be included in the display device 10, and the other portion thereof may be provided separately from the display device 10. For example, the display device 10 may include the display module 11, and the processor 12, the memory 13, and the power module 14 may be provided in the form of other devices in the electronic device 1 rather than the display device 10.

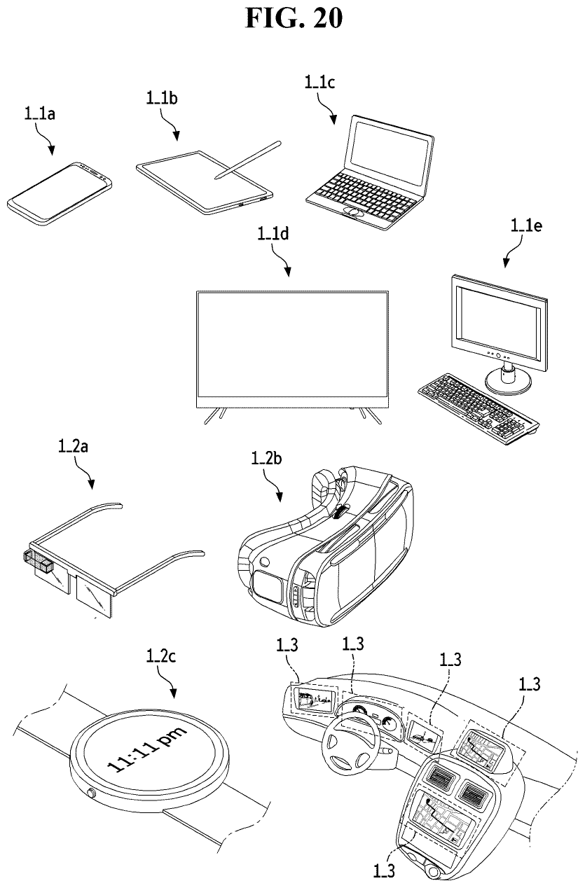

FIG. 20 is a schematic diagram of an electronic device according to various embodiments.

Referring to FIG. 20, various electronic devices 1 to which the display device 10 according to embodiments is applied include an electronic device for image display, such as a smartphone 1_1a, a tablet PC 1_1b, a laptop 1_1c, a TV 1_1d, and a desktop monitor 1_1e, a wearable electronic device 1_2 including a display module such as smart glasses 1_2a, a head mounted display 1_2b, and a smart watch 1_2c, and an electronic device 1_3 for a vehicle including a display module such as a dashboard, a center fascia, a center information display (CID) disposed on a dashboard, and a room mirror display of a vehicle.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A display device comprising:
a substrate;
an element layer on the substrate and comprising a light-emitting element and a light-receiving element; and
a circuit layer between the substrate and the element layer,
wherein the circuit layer comprises:
a first stack comprising a light-emission transistor connected to the light-emitting element;
a first line stack on the first stack and comprising a first line connected to the light-emission transistor;
a second stack on the first line stack and comprising a light-receiving transistor connected to the light-receiving element; and
a second line stack on the second stack and comprising a second line connected to at least one of the light-emission transistor and the light-receiving transistor.

2. The display device of claim 1, wherein the light-receiving transistor does not overlap the light-emission transistor in a first direction perpendicular to an upper surface of the substrate.

3. The display device of claim 1, wherein the light-receiving transistor is overlapped by the light-emission transistor in a first direction perpendicular to an upper surface of the substrate.

4. The display device of claim 1, further comprising a common application line connected to both the light-emission transistor and the light-receiving transistor.

5. The display device of claim 4, wherein the common application line comprises a first end adjacent to the light-emission transistor, a second end adjacent to the light-receiving transistor, and a connection portion connecting the first end to the second end.

6. The display device of claim 5, wherein the first stack further comprises a first insulating film,
wherein the second stack further comprises a second insulating film,
wherein the circuit layer further comprises:
a first contact hole extending through the second insulating film and the first insulating film, and
a second contact hole extending through the second insulating film,
wherein the first contact hole connects the first end of the common application line to the light-emission transistor,
wherein the second contact hole connects the second end of the common application line to the light-receiving transistor, and
wherein the connection portion of the common application line is between the first contact hole and the second contact hole.

7. The display device of claim 4, wherein the common application line comprises at least one of a reference voltage line, an initialization voltage line, a scan write line, and a low voltage power line.

8. The display device of claim 1, wherein the light-receiving transistor is not in the first stack, and
wherein the light-emission transistor is not in the second stack.

9. A display device comprising:
a substrate;
an element layer on the substrate and comprising a light-emitting element and a light-receiving element; and
a circuit layer between the substrate and the element layer,
wherein the circuit layer comprises:
a first active layer on the substrate;
a first gate layer on the first active layer;
a first source/drain layer on the first gate layer;
a second active layer on the first source/drain layer;
a second gate layer on the second active layer;
a second source/drain layer on the second gate layer;
a light-emission transistor connected to the light-emitting element, the light-emission transistor comprising a first semiconductor area, a first electrode, and a second electrode in the first active layer, and a first gate electrode in the first gate layer;
a light-receiving transistor connected to the light-receiving element, the light-receiving transistor comprising a second semiconductor area, a third electrode, and a fourth electrode in the second active layer, and a second gate electrode in the second gate layer;
a first line on the first source/drain layer and connected to the light-emission transistor; and
a second line on the second source/drain layer and connected to at least one of the light-emission transistor and the light-receiving transistor.

10. The display device of claim 9, wherein the light-receiving transistor does not overlap the light-emission transistor in a first direction perpendicular to an upper surface of the substrate.

11. The display device of claim 9, wherein the light-receiving transistor is overlapped by the light-emission transistor in a first direction perpendicular to an upper surface of the substrate.

12. The display device of claim 9, further comprising a common application line connected to both the light-emission transistor and the light-receiving transistor.

13. The display device of claim 12, wherein the common application line comprises a first end adjacent to the light-emission transistor, a second end adjacent to the light-receiving transistor, and a connection portion connecting the first end to the second end.

14. The display device of claim 13, wherein the common application line is in the second source/drain layer.

15. The display device of claim 13, wherein the circuit layer further comprises:
a first connection electrode on the first source/drain layer;
a first contact hole extending through at least one insulating film between the first source/drain layer and the second source/drain layer; and
a second contact hole extending through at least one insulating film between the second active layer and the second source/drain layer,
wherein the first contact hole connects the first end of the common application line to the light-emission transistor,
wherein the second contact hole connects the second end of the common application line to the light-receiving transistor, and
wherein the connection portion of the common application line is between the first contact hole and the second contact hole.

16. The display device of claim 12, wherein the common application line comprises at least one of a reference voltage line, an initialization voltage line, a scan write line, and a low voltage power line.

17. The display device of claim 9, wherein the circuit layer further comprises a first stack comprising the light-emission transistor and a second stack comprising the light-receiving transistor,
wherein the light-receiving transistor is not in the first stack, and
wherein the light-emission transistor is not in the second stack.

18. The display device of claim 9, wherein the circuit layer further comprises:
a first lower conductive layer between the substrate and the first active layer; and
a second lower conductive layer between the first source/drain layer and the second active layer.

19. The display device of claim 18, wherein the light-emission transistor further comprises a first lower gate electrode in the first lower conductive layer, and
wherein the light-receiving transistor further comprises a second lower gate electrode in the second lower conductive layer.

20. An electronic device comprising:
a display device configured to display an image;
a processor configured to provide an image driving signal to the display device; and
a power module configured to supply power to the display device and the processor,
wherein the display device comprises:
a substrate;
an element layer on the substrate and comprising a light-emitting element and a light-receiving element; and
a circuit layer between the substrate and the element layer, and
wherein the circuit layer comprises: a
a first stack comprising a light-emission transistor connected to the light-emitting element;
a first line stack on the first stack and comprising a first line connected to the light-emission transistor;
a second stack on the first line stack and comprising a light-receiving transistor connected to the light-receiving element; and
a second line stack on the second stack and comprising a second line connected to at least one of the light-emission transistor and the light-receiving transistor.
